(19) United States
(12) Patent Application Publication
(10) Pub. No.: US 2005/0133877 A1
(43) Pub. Date: Jun. 23, 2005

(54) Chemical sensor

(76) Inventors: Jacob Thaysen, Copenhagen (DK); Anja Boisen, Birkerod (DK)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/003,467

(22) Filed: Dec. 6, 2004

Related U.S. Application Data
(63) Continuation-in-part of application No. PCT/DK03/00378, filed on Jun. 10, 2003.
(60) Provisional application No. 60/405,306, filed on Aug. 23, 2002.

(30) Foreign Application Priority Data
Jun. 7, 2002 (DK) PA 2002 00884

(51) Int. Cl. H01L 27/14; H01L 29/82; H01L 21/00

(52) U.S. Cl. 257/414; 257/415; 257/417; 438/49

(57) ABSTRACT

The invention concerns a chemical sensor comprising at least one cantilever sensor unit with a capture surface for a chemical substance to be detected. The cantilever comprises a piezoresistor of doped single crystalline silicon with a pair of wires for applying an electrical field over the piezoresistor, and a current shield capable of shielding the piezoresistor electrically from a liquid for a sufficient time to performing a measurement when a liquid sample is applied in contact with the capture surface. The current shield comprises one or more of the materials selected from the group consisting of nitrides, such as silicon nitride, metal oxides, such as aluminium oxide, ceramics, diamond films, silicon carbide, tantalum oxide, single crystalline silicon, glass mixtures and combinations thereof, said current shield preferably comprises one or more of the materials silicon nitride and single crystalline silicon. The invention also relates to methods of preparing such chemical sensor.

This application is a continuation-in-part of International Application Number PCT/DK03/00378, which also claims priority of U.S. Provisional Application No. 60/405,306 and Danish Application No. 2002 00884, the contents of all of which are herein incorporated by reference.

The present invention relates to a chemical sensor comprising one or more sensor units shaped as cantilevers and comprising a capture surface area and a piezoresistive detection system, for direct detection of stress change of the sensor unit.

The invention also relates to a method of producing such sensor.

It is known to use cantilevers for detecting components in fluids such as gas and liquids. In most situations the sensors with cantilevers have optical read out, but also sensors comprising cantilevers with integrated piezoresistors has been described to be useful in detecting components in fluids.

Cantilevers with integrated piezoresistors can e.g. be used as a mass detector. The cantilever is actuated such that it vibrates at its resonant frequency. The resonant frequency changes as a function of the mass situated on the cantilever surface. The change in resonant frequency can be measured by monitoring the change in resistance of the piezoresistor. This is e.g. described in WO 0066266.

Cantilever based sensors with integrated piezoresistors are used as very sensitive mechanical stress sensors. As described in e.g. WO 0066266 and WO 9938007 micro cantilevers can be used for detection of molecular interaction. At least one surface of the cantilever is coated with a capture layer, which reacts with a target molecule of interest. If the cantilever is exposed to a sample in which the target molecule is present, the target molecule will react with the capture molecule on the cantilever surface and a surface stress change is obtained.

Due to the surface stress change the cantilever, a mechanical compression or decompression is applied to the cantilever and thereby also to the piezoresistor, and thereby the resistivity of the piezoresistor changes it value. The mechanical compression or decompression may result in a deflection of the cantilever if only parts of the surface are stressed. By measuring the change in resistance, it can be determined whether the target molecule is present in the sample or not, and if so it is also possibly to detect the concentration of the target molecule.

For stress formation studies in ambient and aqueous environments, micrometer-sized cantilevers with optical read-out have proven very sensitive as described in the articles Berger, R., Gerber, Ch., Lang, H. P. & Gimzewski, J. K. Micromechanics: A toolbox for femtoscale science: “Towards a laboratory on a tip”. Microelectronic Engineering. 35, 373-379 (1997), and O'Shea, S. J., Welland, M. E. Atomic force Microscopy stress sensors for studies in liquids. J. Vac. Sci. Technol. B. 14, 1383-1385 (1996).

Cantilever-based sensors with integrated piezoresistive read-out are described by Thaysen, J., Boisen, A., Hansen, 0. & Bouwstra, S. AFM probe with piezoresistive read-out and highly symmetrical Whetstone bridge arrangement. Proceedings of Transducers'99,1852-1855 (Sendai 1999). Hereby the stress changes on the cantilever sensors can be registered directly by the piezoresistor. Moreover, the inventors have realised that integrated read-out greatly facilitates operation in solutions since the refractive indices of the liquids do not influence the detection. Each sensor may have a built-in reference cantilever, which makes it possible to subtract background drift directly in the measurement.

The objective of the present invention is to provide a chemical sensor comprising one or more flexible sensor units with a capture surface, which chemical sensor can be used for detection of the presence of a chemical component in a with a high signal/noise ratio, even if the chemical component is subjected to a liquid or to moisture prior to or under the detection.

Another objective of the present invention is to provide a method of producing such sensor.

These and other objectives as it will be clear from the following description, has been achieved by the invention as defined in the claims.

According to the invention a very stable sensor has been provided. The sensor of the invention may thus in one embodiment be used in the detection of a chemical component, e.g. a biocomponent in a liquid.

In another embodiment the sensor may be used a gas detector, e.g. in an environment with a moisture level which is not controlled, such as out door. The sensor may thus for example be used as a hand hold device for the detection of explosives. Such a device should be able to withstand moisture for longer time, and still be able to provide reliable detections.

The sensor of the invention comprises one or more sensor units in the form of cantilevers.

A “cantilever” is defined as a sheet formed unit linked to a substrate (or two substrates) along one or two opposite edge lines. A cantilever thus also includes a bridge, as well as a traditional rectangular or leaf shaped cantilever.

“Cantilevers” also includes flexible structures which is linked to and protrudes from a base also called a substrate.

The term “flexible” used in relation to the sensor unit means that the sensor unit should be capable of deflecting, e.g. due to stress formed in the surface stress sensing element or due to amplification using an amplifier.

In one embodiment the cantilever-like structure is a structure that protrudes from a substrate and is capable of being deformed (deflected) due to a deformation force of 10^{31 3} N or less, such as of 10⁻⁵ N or less, such as of 10⁻⁷ N or less, such as of 10⁻⁹ N or less, such as of 10⁻¹⁰ N or less.

In one embodiment, the sensor unit shaped as a cantilever with a longitudinal direction is linked in both of its longitudinal endings to form a cantilevered bridge.

In another embodiment, the cantilever is a traditional rectangular or leaf shaped cantilever linked to only one substrate. In the following this type of cantilever is referred to as cantilever with a free end.

In one embodiment the cantilever is in the form of a sheet-formed unit having a thickness which is thinner than its other dimensions.

The shape and size of the sensor and the size, shape and the number of cantilevered sensor units as well as its wiring, may e.g. be as disclosed in any one of the patent applications WO 0066266, WO 03044530 (PCT/DK/0200779), WO 03071258 (PCT/DK/0300117), WO 03062135 (PCT/DK/0300042), and WO 03067248 (PCT/DK/0300086), which are hereby incorporated by reference.

In the following the sensor is described with one sensor unit but it should be understood that the sensor unit may have several sensor units, such as up to 300, e.g. up to 100.

In one embodiment the cantilever sensor unit is as described in WO 03062135.

In one embodiment the sensor unit is a flexible sheet-formed unit having an average thickness which is thinner than both its average length and its average width, said sensor unit preferably have a thickness of between 500 Å and 5 μm, such as between 1 and 3 μm.

In one embodiment the sensor unit is a flexible sheet-formed unit having an average thickness which is at least 5 times, preferably at least 50 times less than its average width and average length.

The sensor unit has a capture surface for a chemical substance to be detected e.g. in the form of a capture coating. The capture coating may e.g. be as described in any one of the applications WO 03071258 and WO 03062135 or in U.S. Pat. No. 6,289,717, WO 0133226 or WO 0014539, which are hereby incorporated by reference.

In one embodiment of the sensor according to the invention, the capture surface is a surface with a high affinity for explosives, such as TNT. Further information about how to provide surface affinity for explosives on a cantilever can be found in U.S. Pat. No. 5,918,263.

In one embodiment of the sensor according to the invention, the capture surface is a surface of a capture coating comprising a capture layer, wherein the capture layer comprise one or more functional groups selected from the group consisting of acid anhydrides, acid halides, epoxides, aldehydes, carboxylic acids, thiols, and primary amines.

In one embodiment of the sensor according to the invention, the capture surface is a surface of a capture coating comprising a capture layer, wherein said capture layer is a layer comprising one or more components selected from the group consisting of carboxylic acids, esters, acid halides, aldehydes, ketones, alcohols, thiols, disulphides, amines, ethers, halides, hydrazines, succinimides, maleimides saccharides, lecitin, and biotin, avidin.

In one embodiment of the sensor according to the invention, the capture surface is a surface of a capture coating comprising a capture layer, wherein said capture layer is a layer comprising a detection ligand, said detection ligand being a member of a specific binding pair wherein said detection ligand preferably is selected from the group consisting of RNA oligos, DNA oligos, PNA oligos, proteins, peptides, hormones, blood components, antigen and antibodies.

In one embodiment of the sensor according to the invention, the capture surface is a surface of a capture coating comprising a capture layer, wherein said capture layer is a layer comprising a photochemically linked quinone selected from the group consisting of anthraquinones, phenanthrenequinones, benzoquinones, naphthoquinones, said quinones preferably being substituted by a functional group selected from the group consisting of carboxylic acids, sulfonic acid derivatives, esters, acid halides, acid hydrazides, semicarbazides, thiosemicarbaxides, nitriles, aldehydes, ketones, alcohols, thioles, disulphides, amines, hydrazines, ethers, epoxides, maleimides, succinimides, sulphides, halides and derivatives thereof.

Further information about quinones and the method of linking functional groups to a surface via a quinone and optionally a linker can be found in WO 96/31557, WO and 0104129, which are hereby incorporated by, reference.

The quinone may e.g. be linked to one or more of the ligands selected from the group consisting of biotin, toxins, herbicides, pesticides, carbohydrates, antibiotics, cell poisons, steroids, peptides, nucleotides, peptide nucleic acids (PNA) binding partners, nucleic acid binding partners, proteins and haptenes, said one or more ligands optionally being linked to the quinone via a spacer.

The capture coating may in principle comprise two or more layers e.g. up to 10 such as 3 or 5 layers.

In one embodiment, the capture coating layer or capture coating layers comprises one or more compounds selected from the group consisting of cyclodextrin and derivatives thereof, a compound containing a thiol group, a disulphide group, a sulphonate group or a sulphate group, a peptide or polypeptide.

The capture coating could in principle have any thickness. If the capture coating is very thick the sensitivity may be reduced due to stiffness of the sensor unit. A desired thickness could e.g. be from molecular thickness to 2000 nm, such as up to, 2, 5, 10 or 50 molecule layers, or e.g. between 0.5 nm and 1000 nm, such as between 1 and 500 nm, such as between 10 and 200 nm.

The sensor unit comprises a piezoresistor of a semi conductive material. The piezoresistor preferably being of a material selected from the group consisting of doped single crystalline silicon, doped single crystalline silicon germanium (SG) and doped III-V materials.

Semiconductive materials are usually ‘born’ as P-type doped (also called P-doped)or N-type doped (also called N-doped) materials. The doping level or type may however be changed using well known methods.

The III-V materials useful for the piezoresistor may in principle be any type of III-V materials, such as the types disclosed in “Band parameters for III-V compound semiconductors and their alloys”, Vurgaftman et al. Applied physics review, Vol. 89, no. 11, 1 Jun. 2001, pages 5815-5875. Preferred III-V materials include Germanium, Galium Arsenide, Indium Phosphide and composites/heterostructures of these, such as AlₓGa₁₋As, InGaAsP and InGaAlAs.

Methods for processing such III-V materials are well known in the art, and further information can e.g. be found in “P-Ohmic contact resistance for GaAs(C)/GaN(Mg)” Dang et al. Solid-state electronics 44 (2000) 105-109.

In one embodiment the sensor unit comprises a piezoresistor of doped single crystalline silicon (P-doped or N-doped). N-doped piezoresistors are e.g. disclosed in WO 04059306A1 (DK PA 2003 00068) which is hereby incorporated by reference. A piezoresistor of doped single crystalline silicon has been found to exhibit very good properties in the present application. Thus the piezoresistor of doped single crystalline silicon is very sensitive, and the signal to noise ratio is very good compared to known sensors using other types of piezoresistors.

The above good characteristic is also found for single crystalline silicon germanium (SG). SG can be grown epitaxial using single crystalline silicon as a seed layer and a cantilever with a SG piezoresistive element can be fabricated by the same methods as described below for single crystalline silicon.

It has been found the piezoresistivity of SG is comparable to single crystalline silicone and in some cases even better. The SG may be doped to be n or p type using the same techniques as silicon. In Jacob Richter's M.Sc. Thesis: Piezoresistivity in silicon and strained silicon germanium, Department of Micro and Nanotechnology, Technical University of Denmark, September 2004. It was found that p-type Sio_{0.9}Geo_{0.1} had piezoresistive coefficients about 30% WO better for p-type Si.

The piezoresistor may have any shape e.g. as described in any one of the patent applications WO 0066266, WO 03044530, WO 03071258, WO 03062135, WO 03067248 and WO 04059306A1.

The sensor unit also comprise a pair of wires for applying an electrical field over the piezoresistor, e.g. as described in any one of the patent applications WO 0066266, WO 03044530, WO 03071258, WO 03062135, WO 03067248 and WO 04059306A1.

The sensor unit further comprises a current shield. The current shield also referred to as a ‘shield’, totally or partly covers the piezoresistor and thereby shields piezoresistor electrically e.g. from a liquid/moisture when such liquid or moisture is applied in contact with the capture surface.

In one embodiment the current shield is preventing liquid or moisture from the air or from a sample (liquid or gas) to interfere electrically with the piezoresistor, i.e. the liquid or moisture from the air or the sample has no essentially influence of the resistivity of the piezoresistor.

The current shield comprises one or more of the materials selected from the group consisting of nitrides, such as silicon nitride, metal oxides, such as aluminium oxide, ceramics, diamond films, silicon carbide, tantalum oxide, glass mixtures, essentially non doped, P-type or N-type semiconductive material, where the semiconductive material has another type than the type of the piezoresistive element, and combinations thereof, said current shield preferably comprises one or more of the materials silicon nitride and P-type or N-type semiconductive material.

The semiconductive material may e.g. be as above i.e. preferably selected from the group consisting of doped single crystalline silicon, doped single crystalline silicon germanium (SG) and doped III-V materials.

Thus in one embodiment wherein the current shield is of, or comprises single crystalline silicon this current shield single crystalline silicon is either essentially non doped or is n-doped if the piezoresistor is P-doped or is P-doped if the piezoresistor is N-doped.

Due to the combination of doped semiconductive piezoresistor (e.g. single crystalline silicone) and a current shield it is possibly to obtain a detection of the presence of a chemical substance with a high noise signal ratio. In this connection it should also be observed that the current shield can be sufficient thin to allow deformation of the piezoresistor while at the same time being sufficient current shielding to provide low noise due to current leaks. This unique combination is furthermore relatively simple to produce. However it should be observed that the current shield should not be too thin as it would then be fragile, and may be subjected to damage whereby it could provide unreliable detection results. Desired thickness depends on the type of material used for the shield.

In one embodiment the current shield consists essentially of one or more of the materials selected from the group consisting of nitrides, such as silicon nitride, metal oxides, such as aluminium oxide, ceramics, diamond films, silicon carbide, tantalum oxide, single crystalline silicon, poly crystalline silicon, glass mixtures and combinations thereof e.g. in combination with silicon oxide. By the term “consist essentially” means that small amounts (such as up to a total weight percent of 10 or preferably less than 5) of other materials may be present so long this do not change the current shield effect of the current shield.

In one embodiment the current shield comprises silicon nitride. As an example the current shield may be made from a combination of silicon nitride and silicon.

In one embodiment the current shield comprises a layer of silicon nitride. In one embodiment the current shield consists essentially of silicon nitride. Silicon nitride has shown to provide a very good current shield, and thereby a high signal to noise ratio can be obtained.

In one embodiment the current shield has a diffusion barrier which is sufficient to prevent the diffusion of an electrolyte to leak current from the piezoresistor when water is held in contact with the capture surface for a period of 1 minute, preferably even 2 minutes under standard conditions (20° C., and 1 bar).

In one embodiment the shield has a diffusion barrier which is sufficient to prevent the diffusion of an electrolyte to leak current from the piezoresistor when an acidic liquid at a pH of 4 is held in contact with the capture surface for a period of 1 or even 2 minutes or even 10 minutes under standard conditions.

The above shielding properties may be regulated by selecting the thickness and materials of the current shield.

In one embodiment of the chemical sensor according to the invention the piezoresistor is encapsulated in the current shield.

The shield may in one embodiment be coated with, encapsulate by or include one or more layers of other material, such as silicon oxide which in is self cannot provide a sufficient diffusion barrier. By the term ‘the shield include one or more layers of other materials’ is meant that these one or more layers are sandwiched between layers of the shield. If the shield is coated with or encapsulated by such one or more layers of other materials, these one or more layers are not a part of the shield, but a coating onto or encapsulated by the shield.

In one embodiment where the sensor unit is coated with or encapsulates one or more layers of silicon oxide, each layer of silicon oxide, may e.g. have a thickness of between 100 Å and 1 μm.

The total thickness of the sensor unit may in a preferred embodiment be up to about 5 μm, such as between 0.1 and 3 μm.

The sensor unit in the form of a cantilever may in one embodiment comprise a bottom shield layer, a top shield layer, and an edge shield layer. The bottom shield layer, top shield layer and edge shield layer constitute the shield that surrounds the piezoresistive element. In this connection it should be understood that the piezoresistive element is not completely surrounded as it naturally is connected to a pair of wires for applying an electrical field over the piezoresistor.

The shield layers (bottom shield layer, top shield layer and edge shield layer) that surround the cantilever may have equal or different thickness such a thickness between 100 Å and 2 μm, more preferably the thickness of said top shield layer is between 0.05 and 1 times the thickness of the bottom shield layer.

In one embodiment the top shield layer and the edge shield layer are of the same material, said top shield layer and said edge shield layer preferably being of silicon nitride e.g. with a thickness in the range 10-3000 Å.

In one embodiment the bottom shield layer is of single crystalline silicon, polycrystalline silicon and/or silicon nitride e.g. with a thickness in the range 10-3000 Å.

In one embodiment where the piezoresistor is encapsulated by a top shield layer, a bottom shield layer and an edge shield layer, these shield layers further encapsulate one or more intermediate layers of other materials, such as a layer of silicon oxide, preferably applied between the piezoresistor and the bottom layer.

The sensor unit e.g. in the form of a cantilever may further comprise one or more outer layer placed on the outer side of the shield. Such outer layer placed outside the shield may e.g. be a layer of silicon oxide.

The capture coating may also be placed outside the shield. In one embodiment the shield also constitute or is a part of the capture coating to provide the capture surface.

The capture coating may in one embodiment where the sensor unit is a cantilever, be placed on the top layer of the shield. In this embodiment the bottom layer of the shield or layers coated thereto may e.g. be free of capture coating or contain less active capture coating than the top layer of the shield or layers thereon. Thereby the cantilever will deflect when bio components are captured on the capture surface.

In one embodiment, where the capture surface is applied so that stress from the capture surface deflects the cantilever, the thickness of the material layer or layers on one major side of the piezoresistor is 5 times thicker or more than the material layer or layers on the other major side of the piezoresistor. Thereby the sensitivity of the piezoresistor may be increased. In this embodiment it is desired that the capture coating is placed on one of the major surfaces of the cantilever only.

The chemical sensor may preferably comprise one or more sample chambers e.g. gas chamber or liquid chambers. In one embodiment the one or more sensor units partly or totally protrudes into the sample chamber(s) so that a liquid applied in the chamber is capable of coming into contact with part of the surface of the sensor unit(s).

The sample chamber or chambers may e.g. be in the form of interaction chamber(s), preferably comprising a channel for feeding a liquid into the interaction chamber(s).

In one embodiment at least 50%, more preferably substantially the entire capture surface of the sensor unit is positioned inside the interaction chamber(s).

The invention also relates to methods of preparing a chemical sensor as described above.

In the following methods of producing a sensor with a piezoresistor of single crystalline silicon is described. Similar methods using wafers of other semiconductive materials such a wafers of single crystalline silicon germanium (SG) and III-V materials, could be used.

A first method comprises the steps of:
i. providing a first substrate with a first major surface in the form of a wafer of single crystalline silicon,
ii. optionally providing the first major surface of the first substrate with one or more material layers,
iii. providing a second substrate with a first major surface in the form of a wafer of single crystalline silicon,
iv. injecting ions into the second substrate to form a weakening plane substantially parallel to the first major surface through the material,
v. doping at least some of the single crystalline silicon between the first major surface and the weakening plane with a doping to form a piezoresistor,
vi. optionally providing the first major surface of the second substrate with one or more material layers,
vii. merging the first and the second substrate by bringing the first major surfaces with optional layers together,
viii. removing along the weakening plane the part of the second substrate turning away from the first surface thereof,
ix. etching away a part of the first substrate to form a cantilever,
x. applying a layer of the shield material to encapsulate the piezoresistor .

The individually steps of the first method may be performed in the order as mentioned but the order of steps may also be performed in a different order, provided that step i is performed before steps ii and steps vii-x; step iii is performed before steps iv-x; and step iv is performed before steps viii-x.

Information about how to carry out the individual steps, may be found in “properties of Nitrogen-Implanted SOI Substrates”, by Stanley W. Polchlopek et al, IEEE Transaction on electron devices. Vol. 40.No. 2, February 1993; “Basic mechanism involved in the Smart-Cut® process” by B. Aspar et al. Microelectronic engineering, 36 (1997) 223-240; “Application of hydrogen ion beams to silicon on insulator material technology” by Michel Bruel. Nuclear Instruments and Methods in Physics Research B 108 (1996) 313-319; “Ultrashallow junctions or ultrathin SOI?” by M. I. Current et al. Solidstate Technology, September 2000; “New technologies for silicon-insulator”. European semiconductor, February 2002; and “Enviromental sensors based on micromashined cantilevers with integrated read-out” by Anja Boisen et al. Ultramicroscopy 82 (2000) 11-16.

When using SG as piezoresistor, the basis material may e.g. be fabricated using the following method: Growing SG on a SOI wafer which is bonded to a wafer coated with SiN, the SOI handle wafer is etched or grinded away and the silicon seed layer is etched selectivity towards the SG layer. Hereby a SG layer on silicon nitride is obtained.

In one embodiment using single crystalline silicon as piezoresistor, the basis material may e.g. be fabricated using the following method: Providing a first SOI wafer and merging bonding it to the SIN side of a wafer coated with SiN, the SOI handle wafer is etched or grinded away.

The first substrate may in one embodiment be a wafer of p-type single crystalline silicon.

In one embodiment this first substrate is provided with a layer of silicon oxide.

The second substrate may e.g. be predoped, but often this second substrate may be an essentially undoped silicon wafer as the first substrate.

A weakening plan is performed in the second substrate. The weakening plan should preferably be substantially parallel with first major surface of the material. The weakening plan may e.g. be performed by Smart-Cut® or NanoCleave as described in the article above.

At least some of the single crystalline silicon between the first major surface and the weakening plane with a doping to form a piezoresistor. The doping may e.g. be made by ion-implanting e.g. as described in the article above. The ions may e.g. be boron ions.

Before or after the doping the single crystalline silicon to provide the piezoresistor, the piezoresistor may be provided with the desired shape by defining it using standard photolithography and subsequent etching of the resist pattern.

Before or after the doping the first major surface of the second substrate may e.g. be provided with one or more material layers. This may e.g. be performed by forming a silicon oxide layer on the surface e.g. as described in the above articles.

The first and the second substrates are merged by bringing the first major surfaces with optional layers together. This may e.g. be performed as described in the above articles.

The part of the second substrate turning away from the first surface thereof is removed or cleaved of e.g. as described in the articles above in connection with the Smart-Cut® or NanoCleave methods.

The merged substrate is now used as starting point for an etching process for preparing the chemical sensor. The cantilever and contact holes for electrical contact to the piezoresistor may be defined by standard photolithography and subsequently etching of the cantilever and contact hole pattern. The cantilever may be released by underetching, for example performed in KOH.

The chemical sensor may e.g. be prepared there from using ordinary etching steps e.g. as disclosed in “Atomic force microscopy probe with piezoresistive read-out and highly symmetrical Wheatstone bridge arrangement” by Anja Boisen. Sensors and Actuators 83 (2000) 47-53; or in any one of the patent applications WO 0066266, PCT/DK/0200779, PCT/DK/0300117, PCT/DK/0300042, and DK PCT/DK/0300086.

Finally a layer of the shield material is applied to encapsulate the piezoresistor, e.g. by use of one of the methods as described in the above article, e.g. the method of implanting nitrogen
In a second method of preparing a chemical sensor, the method comprises the steps of
i. providing a substrate with a first major surface in the form of a wafer of single crystalline silicon,
ii. injecting nitride ions into the substrate to form a silicon nitride layer in a plane substantially parallel to the first major surface through the material,
iii. doping at least some of the single crystalline silicon between the first major surface and the silicon nitride layer with a doping to form a piezoresistor,
iv. optionally providing the first major surface of the substrate with one or more material layers,
v. etching away a part of the first substrate to form a cantilever,
vi. applying a layer of the shield material to encapsulate the piezoresistor.

The injecting of nitride ions into the substrate to form a silicon nitride layer in a plane substantially parallel to the first major surface through the material, may e.g. be performed as described in the article above.

The remaining steps may be performed as described above for the first method.

### DRAWINGS

FIG. 1 is a sectional side cut of a part of a chemical sensor comprising a sensor unit.

FIG. 2 is a sectional side cut of a part of another chemical sensor comprising a sensor unit.

FIG. 3 is a sectional top cut of the part of the chemical sensors shown in the FIGS. 1 and 2.

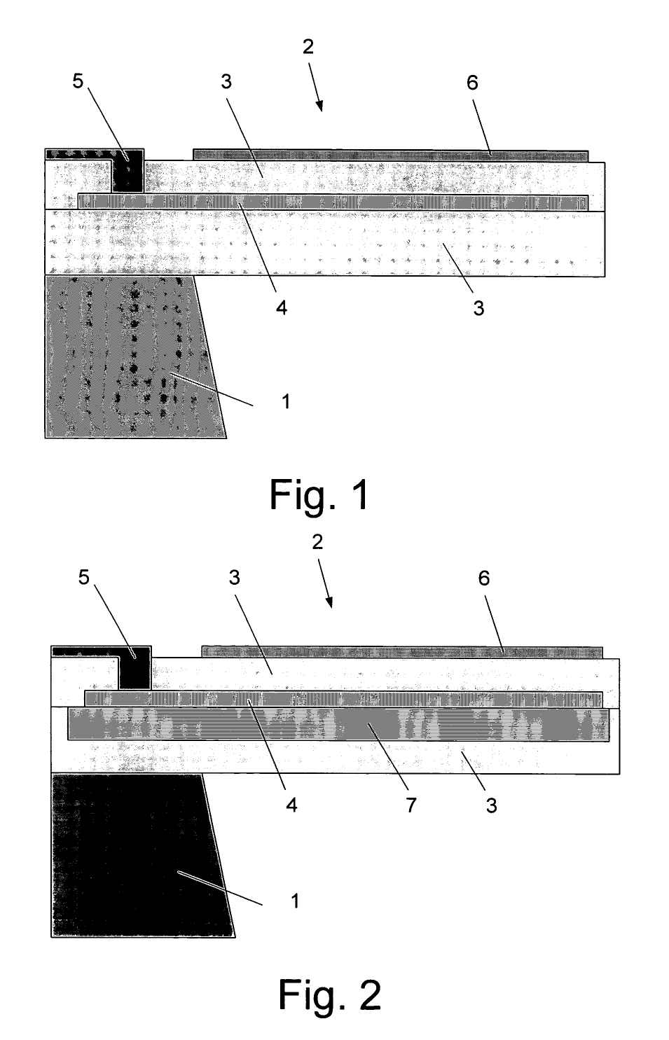

In FIG. 1 the base 1 of a chemical sensor comprising a sensor unit 2 in the form of a cantilever is shown. The cantilever 2 comprises a shield of silicon nitride 3. The silicon nitride encapsulates a piezoresistor 4 in the form of a horse shoe formed single crystalline doped silicon unit. Connection metal wires 5 of metal 5 are linked to the piezoresistor to apply a field over the piezoresistor. A capture coating 6 is applied onto the major upper surface of the cantilever 2.

In FIG. 2 shows a chemical sensor similar to the chemical sensor shown in FIG. 1 but wherein a layer of silicon oxide 7 is contained inside the shield 3. The reference numbers in FIG. 2 have the same meaning as in FIG. 1.

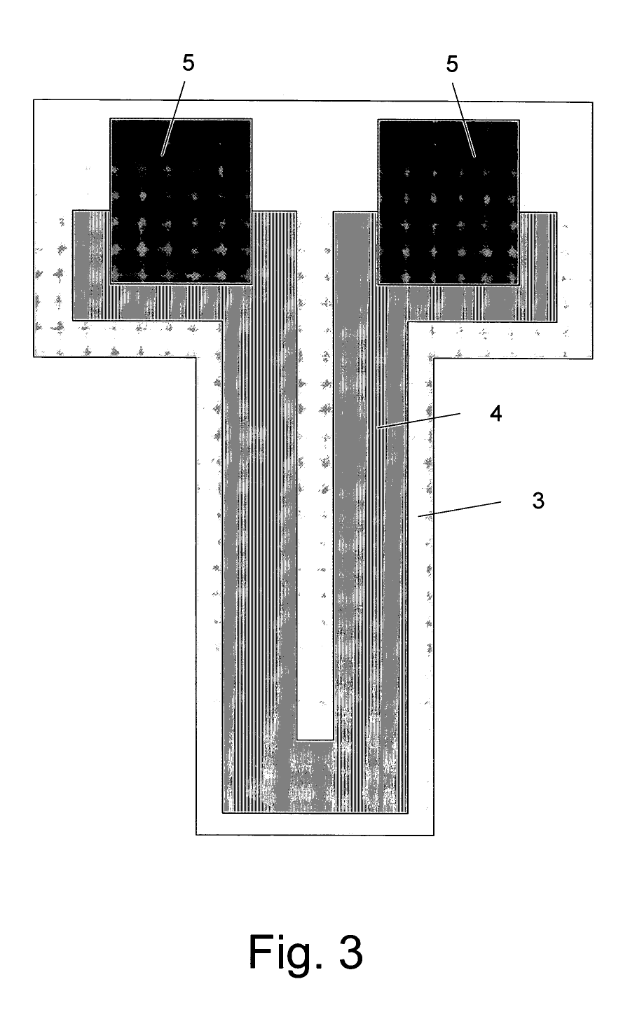

The chemical sensor shown in FIGS. 1 and 2 has an identical top cut as shown in FIG. 1. The reference numbers in FIG. 3 has the same meaning as in FIGS. 1 and 2.

1. A chemical sensor comprising at least one sensor unit in the form of a cantilever having a capture surface for a chemical substance to be detected, a piezoresistor of semiconductive material, with a pair of wires for applying an electrical field over the piezoresistor, and a current shield shielding the piezoresistor electrically, said current shield comprises at least one material chosen from nitrides, metal oxides, ceramics, diamond films, silicon carbide, tantalum oxide, semiconductive materials, glass mixtures and combinations thereof.

2. A chemical sensor as claimed in claim 1, wherein said current shield is capable of shielding the piezoresistor electrically, from a liquid for a sufficient time to perform a measurement when a liquid sample is applied in contact with the capture surface.

3. A chemical sensor as claimed in claim 1, wherein said current shield is encapsulating the piezoresistor, except from the pair of wires for applying an electrical field over the piezoresistor.

4. A chemical sensor as claimed in claim 1, wherein said current shield is preventing liquid or moisture from the air to interfere electrically with the piezoresistor.

5. A chemical sensor as claimed in claim 1, wherein said current shield is preventing liquid or moisture from a sample to interfere electrically with the piezoresistor.

6. A chemical sensor as claimed in claim 1, wherein said piezoresistor comprises at least one semiconductive material chosen from doped single crystalline silicon, doped single crystalline silicon germanium (SG) and doped III-V materials.

7. A chemical sensor as claimed in claim 1, wherein said piezoresistor is a semiconductive material chosen from doped single crystalline silicon, doped single crystalline silicon germanium (SG) and doped III-V materials.

8. A chemical sensor as claimed in claim 1, wherein said current shield comprises at least one material chosen from silicon nitride and single crystalline silicon.

9. A chemical sensor as claimed in claim 1 wherein a said current shield consists essentially of at least one material chosen from nitrides, metal oxides, ceramics, diamond films, silicon carbide, tantalum oxide, semi conductive material, poly crystalline silicon, glass mixtures and combinations thereof.

10. A chemical sensor as claimed in claim 1 wherein said nitride is silicon nitride.

11. A chemical sensor as claimed in claim 1 wherein said metal oxide is aluminium oxide.

12. A chemical sensor as claimed in claim 1 wherein said current shield has a diffusion barrier which is sufficient to prevent the diffusion of an electrolyte to leak current from the piezoresistor when water is in contact with the capture surface for a period of 1 minute.

13. A chemical sensor as claimed in claim 1 wherein the piezoresistor is encapsulated in the current shield, and said current shield consists essentially of silicon nitride.

14. A chemical sensor as claimed in claim 1 wherein the piezoresistor is encapsulated in the current shield, and said current shield consists essentially of silicon nitride in combination with silicon selected from single crystalline silicon or poly crystalline silicon.

15. A chemical sensor as claimed in claim 1 wherein said sensor unit comprises at least one layer of silicon oxide.

16. A chemical sensor as claimed in claim 1 wherein said cantilever comprises a bottom shield layer, a top shield layer, and an edge shield layer, wherein said bottom shield layer, top shield layer and edge shield layer constitute the shield.

17. A chemical sensor as claimed in claim 16 wherein said shield layers have a thickness ranging from 100 Å to 2 μm.

18. A chemical sensor as claimed in claim 16 wherein said top shield layer and said edge shield layer being of the same material.

19. A chemical sensor as claimed in claim 16 wherein said bottom shield layer is silicon chosen from single crystalline silicon, polycrystalline silicon and silicon nitride.

20. A chemical sensor as claimed in claim 16 wherein said top shield layer, bottom shield layer and edge shield layer further encapsulate at least one intermediate layer of another material.

21. A chemical sensor as claimed in claim 20, wherein said top shield layer, bottom shield layer and edge shield layer encapsulate at least one intermediate layer of silicon oxide.

22. A chemical sensor as claimed in claim 16 wherein the cantilever comprises at least one outer layer placed on the outer side of at least one of the top shield layer, bottom shield layer and edge shield layer.

23. A chemical sensor as claimed in claim 22 wherein said outer layer is silicon oxide.

24. A chemical sensor as claimed in claim 16 wherein the capture surface being the surface of a capture coating placed on the outer side of the top shield layer.

25. A chemical sensor as claimed in claim 1 wherein the thickness of the at least one material layer on one major side of the piezoresistor is 5 times or more the thickness of the at least one material layer on the other major side of the piezoresistor.

26. A chemical sensor as claimed in claim 1 wherein said capture surface is a surface of a capture coating comprising a capture layer, wherein said capture layer is a layer comprising at least one functional group chosen from acid anhydrides, acid halides, epoxides, aldehydes, carboxylic acids, thiols, and primary amines.

27. A chemical sensor as claimed in claim 1 wherein said capture surface is a surface of a capture coating comprising a capture layer, wherein said capture layer is a layer comprising at least one component chosen from carboxylic acids, esters, acid halides, aldehydes, ketones, alcohols, thiols, disulphides, amines, ethers, halides, hydrazines, succinimides, maleimides saccharides, lecitin, biotin and avidin.

28. A chemical sensor as claimed in claim 1 wherein said capture surface is a surface of a capture coating comprising a capture layer, wherein said capture layer is a layer comprising a detection ligand, said detection ligand being a member of a specific binding pair.

29. A chemical sensor as claimed in claim 1, wherein said detection ligand is chosen from RNA oligos, DNA oligos, PNA oligos, proteins, peptides, hormones, blood components, antigen and antibodies.

30. A chemical sensor as claimed in claim 1 wherein the capture surface is a surface with an affinity for explosives.

31. A chemical sensor as claimed in claim 1 wherein said sensor unit comprises at least one sample chamber, wherein said sensor unit partly or totally protrudes into said sample chamber so that a sample applied in the sample chamber is capable of coming into contact with at least part of the surface of the sensor unit.

32. A chemical sensor as claimed in claim 31 wherein at least one cantilever is protruding into the at least one sample chamber so that both top and bottom sides of the cantilever is capable of coming into contact with said sample.

33. A chemical sensor comprising at least one sensor unit in the form of a cantilever having a capture surface for a chemical substance to be detected, a piezoresistor of semiconductive material with a pair of wires for applying an electrical field over the piezoresistor, and a current shield having a thickness ranging from 100 Å to 2 μm, said current shield comprises at least one material chose from nitrides, metal oxides, ceramics, diamond films, silicon carbide, tantalum oxide, single crystalline silicon, doped single crystalline silicon germanium (SG), doped III-V materials, glass mixtures and combinations thereof.

34. A chemical sensor as claimed in claim 33, wherein the nitride is silicon nitride.

35. A chemical sensor comprising at least one sensor unit in the form of a cantilever having a capture surface for a chemical substance to be detected, a piezoresistor of semiconductive material with a pair of wires for applying an electrical field over the piezoresistor, and a current shield, which the current shield is sufficient to prevent the diffusion of an electrolyte to leak current from the piezoresistor when water is held in contact with the capture surface for a period of 1 minute at 20° C. and 1 bar, said current shield comprises one or more of the materials selected from the group consisting of nitrides, such as silicon nitride, metal oxides, ceramics, diamond films, silicon carbide, tantalum oxide, single crystalline silicon, doped single crystalline silicon germanium (SG), doped III-V materials, glass mixtures and combinations thereof.

36. A method of preparing a chemical sensor comprising a sensor unit having a capture surface, a piezoresistor and a current shield, said method comprising the steps of
i. providing a first substrate with a first major surface in the form of a wafer of a semiconductive material chosen from single crystalline silicon, single crystalline silicon germanium (SG) and III-V materials,
ii. optionally providing the first major surface of the first substrate with one or more material layers,
iii. providing a second substrate with a first major surface in the form of a wafer of a semiconductive material chosen from single crystalline silicon, single crystalline silicon germanium (SG) and III-V materials,
iv. injecting ions into the second substrate to form a weakening plane substantially parallel to the first major surface through the material,
v. doping at least some of the semiconductive material between the first major surface and the weakening plane with a doping to form a piezoresistor,
vi. optionally providing the first major surface of the second substrate with one or more material layers,
vii. merging the first and the second substrate by bringing the first major surfaces with optional layers together,
viii. removing along the weakening plane of the part of the second substrate turning away from the first surface thereof,
ix. etching away a part of the first substrate to form a cantilever,
x. applying a layer of the shield material to encapsulate the piezoresistor.

37. A method of preparing a chemical sensor comprising a sensor unit having a capture surface, a piezoresistor and a current shield shielding the piezoresistor electrically from a liquid when such liquid is applied in contact with the capture surface, said method comprising the steps of
i. providing a substrate with a first major surface in the form of a wafer of single crystalline silicon,
ii. injecting nitride ions into the substrate to form a silicon nitride layer in a plane substantially parallel to the first major surface through the material,
iii. doping at least some of the single crystalline silicon between the first major surface and the silicon nitride layer with a doping to form a piezoresistor,
iv. optionally providing the first major surface of the substrate with one or more material layers,
v. etching away a part of the first substrate to form a cantilever,
vi. applying a layer of the shield material to encapsulate the piezoresistor.
